(19) United States
(12) Patent Application Publication
(10) Pub. No.: US 2025/0308915 A1
(43) Pub. Date: Oct. 2, 2025

(54) SELECTIVE ETCHING OF SILICON ADJACENT TO SILICON-GERMANIUM

(71) Applicant: Tokyo Electron Limited, Tokyo (JP)

(72) Inventors: Hamed Hajibabaeinajafabadi, Albany, NY (US); Toshiki Kanaki, Albany, NY (US); Subhadeep Kal, Albany, NY (US)

(21) Appl. No.: 18/620,111

(22) Filed: Mar. 28, 2024

(51) Int. Cl. H01L 21/3105; H01L 21/02; H01L 29/06; H01L 29/423; H01L 29/66

(52) U.S. Cl. CPC H01L 21/31056; H01L 21/02211; H01L 21/02532; H10D 62/121; H10D 30/014; H10D 30/6735

(57) ABSTRACT

A process for forming at least portions of an FET includes receiving a substrate comprising epitaxially grown nanosheets of alternating silicon layers and silicon-germanium layers, selectively oxidizing the silicon-germanium layers relative to the silicon layers, exposing the nanosheets to a small molecular species comprising a first functional group and a second functional group. The process also includes heating the nanosheets and the small molecular species to attach the first functional group to the silicon-germanium layers and to vaporize the second functional group, and selectively etching at least a portion of the silicon layers isotropically using an etching gas, where the first functional group selectively retards etching of the silicon-germanium layers.

### TECHNICAL FIELD

The present disclosure relates generally to semiconductor fabrication, and, in particular implementations, to selective etching of silicon (Si) adjacent to silicon-germanium (SiGe).

### BACKGROUND

Generally, a semiconductor integrated circuit (IC) is fabricated by sequentially depositing conductive, dielectric, and semiconductor layers over a semiconductor substrate to form IC devices. Semiconductor processing includes patterning layers using photolithography and etch to form electronic and interconnect elements like transistors, resistors, capacitors, metal lines, contacts, and vias in one monolithic structure.

The semiconductor industry has traditionally followed Moore's Law, which was initially based on the observation that the number of transistors on a chip doubles approximately every two years, leading to a cadence of shrinking feature sizes (also referred to as “scaling”) along with improvements in performance and reductions in costs. However, as transistor features approached atomic dimensions, maintaining this pace has become increasingly challenging. As a result, the scaling cadence has evolved from a strict focus on gate length reduction to a more complex one incorporating innovations in 3D structures, new materials, and integration methods.

Nanosheet transistors have emerged as a promising advancement in this endeavor, representing a significant evolution from their planar and FinFET predecessors. Nanosheet transistors, characterized by their multiple horizontal sheets, or ‘nanosheets’, of channel material stacked vertically, allow for enhanced control over the current flow and offer the potential for further scaling beyond the limits of conventional FinFET architectures. These devices can effectively maintain excellent electrostatic control over a channel and enable gate-all-around (GAA) configurations, which are imperative for next-generation integrated circuits and high-performance computing applications. Despite the advantages of nanosheet transistors, challenges remain in fabrication techniques, uniformity across large wafers, thermal management, and integration with existing manufacturing processes.

### SUMMARY

In one aspect, first method for of selective etching of silicon is disclosed. The first method can include selectively oxidizing a silicon-germanium layer in a composite structure having the silicon-germanium layer and a silicon layer adjacent to the silicon-germanium layer, and exposing the composite structure to a first concentration of a small molecule comprising a methylamine group and a methylsilane group. In any of the disclosed implementations, the first method can include etching the composite structure to selectively remove at least some of the silicon layer, where the methylsilane group is adsorbed on exposed surfaces of the silicon-germanium layer and retards etching of the silicon-germanium layer.

In a further aspect, a first process for forming an FET is disclosed. The first process can include receiving a substrate comprising epitaxially grown nanosheets of alternating silicon layers and silicon-germanium layers, selectively oxidizing the silicon-germanium layers relative to the silicon layers, exposing the nanosheets to a small molecular species comprising a first functional group and a second functional group. The first process can also include heating the nanosheets and the small molecular species to attach the first functional group to the silicon-germanium layers and to vaporize the second functional group, and selectively etching at least a portion of the silicon layers isotropically using an etching gas, wherein the first functional group selectively retards etching of the silicon-germanium layers.

In yet another aspect, a second process for fabricating an FET is disclosed. The second process can include receiving a substrate comprising alternating silicon nanosheets and silicon-germanium nanosheets, and performing a cyclic etch process to selectively etch the silicon nanosheets. In the second process, each cycle of the cyclic etch process can include selectively oxidizing the silicon-germanium nanosheets to leave hydroxyl groups at the silicon-germanium nanosheets, exposing the silicon-germanium nanosheets and the silicon nanosheets to a small molecular species comprising an organic functional group and a silicon containing functional group, annealing the substrate, and exposing the substrate to an etching process to isotropically etch a portion of the silicon nanosheets selective with respect to the silicon-germanium nanosheets.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1A is a depiction of an FET structure during fabrication, in some implementations;

FIG. 1B is a depiction of an FET structure during fabrication, in some implementations;

FIG. 1C is a depiction of a GAA-FET, in some implementations;

FIG. 2 is a flowchart depicting a method of selective etching of silicon, in some implementations;

FIGS. 3A, 3B, 3C, 3D, and 3E are depictions of a process for selective etching of silicon, in some implementations;

FIG. 4 is a multiplot depicting selected x-ray photoelectron spectra, in some implementations;

FIG. 5 is a flowchart depicting a method of selective etching of silicon, in some implementations;

FIG. 6 is a flowchart depicting a process of selective etching of silicon, in some implementations;

FIGS. 7A and 7B are flowcharts of a process of selective etching of silicon, in some implementations; and

FIG. 8 is a depiction of a gas processing system 800, in some implementations.

### DETAILED DESCRIPTION

This disclosure describes selective etching of silicon (Si) near silicon-germanium (SiGe), such as during etching of elevated layered structures, including layered nanosheets, during fabrication of gate-all-around field effect transistors (GAA-FET), in various implementations.

In the following description, details are set forth by way of example to facilitate discussion of the disclosed subject matter. It will be be apparent to a person of ordinary skill in the field, however, that the disclosed implementations are exemplary and not exhaustive of all possible implementations.

Throughout this disclosure, a hyphenated form of a reference numeral refers to a specific instance of an element and the un-hyphenated form of the reference numeral refers to the element generically or collectively. Thus, as an example (not shown in the drawings), device “12-1” refers to an instance of a device class, which may be referred to collectively as devices “12” and any one of which may be referred to generically as a device “12”. In the figures and the description, like numerals are intended to represent like elements.

As noted, recent advances in IC transistor design have included FIN-FETs in an effort to realize smaller device sizes, higher circuit densities, and lower power consumption. With the FIN-FET, the active channel region is elevated over the substrate and can surround source/drain channels on three sides, as opposed to prior planar designs that provided one side or one plane of gate field control and active channel geometry.

A further development based on FIN-FETs are GAA-FETs that continue the elevated source/drain transistor design but further isolate the source/drain channels from the substrate. In a GAA-FET, the gate structure is a central pillar between the source/drain channels, as in the FIN-FET, but in the GAA-FET the source/drain channels are horizontal and surrounded by the gate structure on all four sides, so as to ‘protrude’ at an elevated position from either side of the gate structure. Thus, in the GAA-FET, each source/drain channel has an active channel portion that ‘penetrates’ the gate structure at the elevated position from the substrate, while multiple such source/drain channel pairs can be fabricated for each gate structure. Because the gate structure surrounds the source/drain channel on all four sides, the channel width under gate control is longer for the same device footprint. As a result, GAA-FETs can sustain higher drive current, while improving gate channel control and reducing short-channel effects, which are desirable improvements. The source/drain channels can be fabricated in the form of nanowires or nanosheets, in various implementations, while different types of GAA gate geometries have been developed, including horizonal gates and vertical gates.

The GAA-FET horizontal source/drain channel structure surrounded by a vertical gate arrangement can be beneficial for a number of reasons, even as the fabrication steps for GAA-FETs may be more complex than for prior designs. The fabrication steps for GAA-FETs can include lithography, epitaxy, and selective etching, among other steps. The GAA-FET can provide a smaller footprint for a given cell area, and thus, can increase IC density, which is desirable. GAA-FETs can result in decreased gate leakage current and therefore, increased performance. Also, GAA-FETs can be designed or dimensioned for particular applications, for example by tailoring the channel width for higher performance or reduced power consumption, in particular implementations, such as by defining the dimensions of the source/drain channels, or a number of the source/drain channels per gate, which can vary within a given IC design, as desired. In particular implementations, GAA-FETs can be implemented with different numbers of horizontal source/drain channels, such as two (2), three (3), or four (4) channels, among other configurations.

In particular, the source/drain terminals in GAA-FETs can be formed by growing multiple alternating layers of silicon (Si) and silicon-germanium (SiGe) vertically from the substrate using epitaxy. Epitaxial growth of the source/drain channels for GAA-FETs can provide clean interfaces between the alternating layers so as to preserve remaining material to achieve desired source/drain channel dimensions, such as in the final nanosheet form of the layers. In the GAA-FET fabrication process, an inner spacer between the nanosheets as well as a gate spacer in place of the final gate material can be used. In typical designs, a channel release step selectively etches away the silicon-germanium nanosheets to leave the source/drain channels formed with epitaxial silicon. Accordingly, various wet etch chemistries for silicon versus silicon-germanium having selectivity for etching silicon-germanium have been developed, while it has been observed that such selectivity increases as the germanium content increases.

Thus, both p-type and n-type GAA-FETs can be fabricated using silicon source/drain channels. In particular, etch selectivity favoring etching of silicon-germanium when adjacent to silicon facilitates the use of silicon source/drain channels in GAA-FETs. However, in further developments, fabrication of a p-type GAA-FET using silicon-germanium source/drain channels as nanowires or nanosheets is also a desired implementation. Similar process steps can be used to form silicon-germanium source/drain channels as are used to form silicon source/drain channels, including epitaxial growth of alternating Si and SiGe nanosheet or nanowire layers. One roadblock in the fabrication of such silicon-germanium source/drain channels for p-type GAA-FETs, therefore, is the ability to selectively etch away the silicon layers while leaving the silicon-germanium layers intact, which can involve overcoming chemical selectivity that favors etching away the silicon-germanium layers.

Accordingly, typical approaches to selectively etching silicon adjacent to silicon-germanium, such as in epitaxially-grown alternating layers, have focused on providing a protective surface layer over the silicon-germanium, such as by oxidation or nitridization of the SiGe surface, and then using plasma-assisted etching to remove the exposed Si portions. These kinds of approaches using protective surface oxides or nitrides for silicon-germanium with plasma-assisted etching have typically not resulted in a sufficiently smooth and homogenously etched source/drain channel structure, which is undesirable for fabrication of GAA-FETs. Furthermore, when an oxygen containing plasma is used for etching, the selectivity of the resulting etch process can exhibit poor selectivity for oxides. Also, when a nitrogen containing plasma is used for etching, the selectivity of the resulting etch process can exhibit poor selectivity between silicon and silicon-germanium.

In certain implementations, selective etching of silicon adjacent to silicon-germanium that is suitable for forming source/drain channels of GAA-FETs is disclosed. Certain implementations can employ selective adsorption of a small molecule on the silicon-germanium surface to promote selective etching of silicon adjacent to silicon-germanium using an etchant gas, such as a molecular gas or a remote plasma that can be nonionic. Certain implementations can provide a combination of surface oxidation of the silicon-germanium surface to facilitate adsorption of the small molecule. Certain implementations can provide for selective isotropic etching of silicon when the small molecules are adsorbed on the silicon-germanium surface. Certain implementations are suitable for forming horizontal nanosheets of silicon-germanium as source/drain channels with a vertical gate structure. Certain implementations can be used to fabricate p-type GAA-FETs having silicon-germanium source/drain channels.

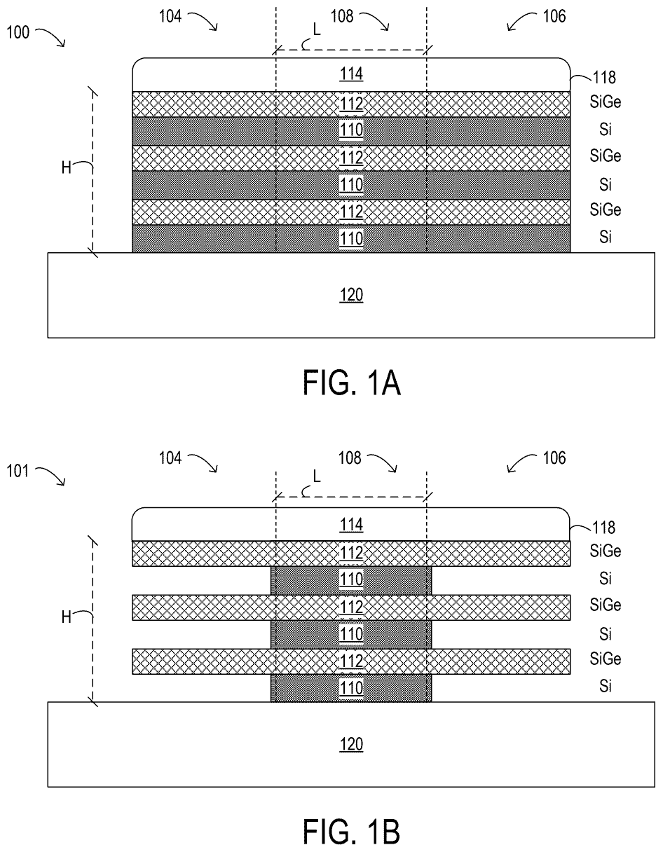

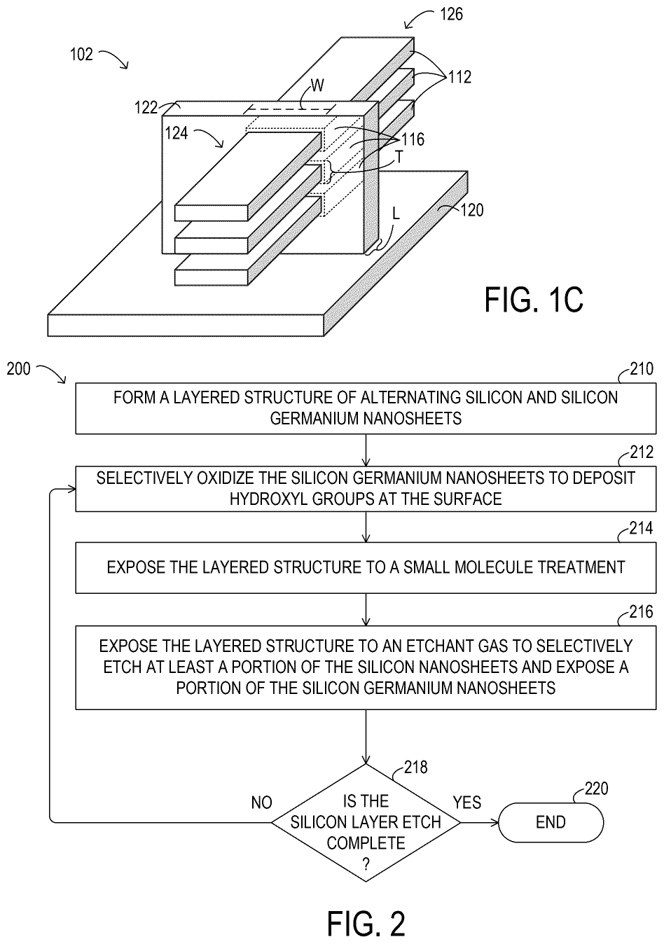

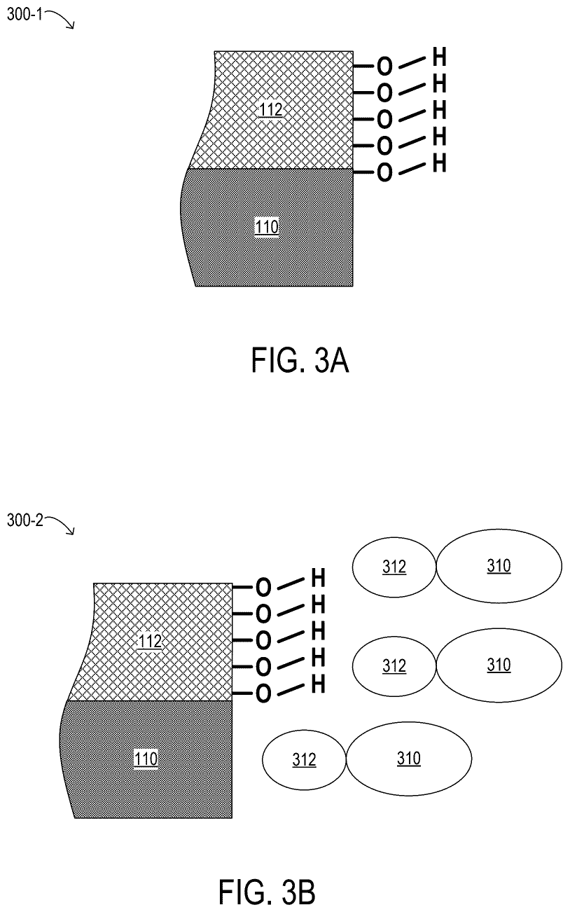

Turning now to the drawings, FIG. 1A is a depiction of an FET structure 100 during fabrication, in certain implementations. FET structure 100 is shown in a schematic depiction and is not necessarily drawn to scale or perspective. In particular, FET structure 100 can depict selected elements of a GAA-FET, such as at an intermediate state in the fabrication process. In FIG. 1A, FET structure 100 is shown in an elevation view, such as a lateral view.

In FIG. 1A, FET structure 100 is shown with a substrate 120 that supports a channel pillar structure 118 covered by a hard mask 114. Specifically, channel pillar structure 118 is shown divided into three regions, namely a source channel pillar 104 at one end, a drain channel pillar 106 at an opposing end, and a gate region 108 that comprises a center portion of channel pillar structure 118. As shown in FIG. 1A, source channel pillar 104 and drain channel pillar 106 can be equivalent structures. At gate region 108, in subsequent processing steps, a gate structure can be formed, such as in the shape of a vertical gate pillar (see also FIG. 1C). As shown, FET structure 100 including source channel pillar 104 and drain channel pillar 106 is depicted schematically and may be different from an actual device that is formed during various types of FET fabrication processes, and is shown for descriptive purposes for explaining selective etching of silicon adjacent to silicon-germanium, as disclosed herein. For example, when channel pillar structure 118 is etched to form a vertical pillar, the sides of channel pillar structure 118 may not be vertical, but may be tapered in profile as a result of an etching process.

In FIG. 1A, source channel pillar 104 and drain channel pillar 106 can be formed by growing alternating layers of silicon and silicon-germanium. As noted, the growth of channel pillar structure 118 can result from an epitaxial growth process that forms sharp boundaries between individual layers, which is desirable for fabricating an FET. Thus, various dimensions for channel pillar structure 118 can be selected, as desired. As shown in FIG. 1A, channel pillar structure 118 has a height H, while each layer is shown having a uniform thickness. It is noted that in various embodiments, height H, a number of layers, a width of channel pillar structure 118, and a length of channel pillar structure 118 can be variously dimensioned, according to desired design parameters for the FET.

In the exemplary implementation of FIG. 1A, channel pillar structure 118 is shown comprising three alternating layers of a Si layer 110 and a SiGe layer 112. When a width and a thickness of individual layers in channel pillar structure 118 is about equivalent, such that a cross-sectional area is about square shaped, channel pillar structure 118 can be described as being formed as nanowires. When the width is greater than the thickness of individual layers in channel pillar structure 118, such that the cross-sectional area is rectangular, channel pillar structure 118 can be described as being formed as nanosheets. Thus, while the dimensions of channel pillar structure 118 can vary, the thickness and the width of an individual layer can be in the nanometer range, such as less than 50 nm, less than 20 nm, or less than 10 nm, in particular implementations.

As shown in FIG. 1A, a gate length L between an inner face of source channel pillar 104 and drain channel pillar 106 indicates the length of gate region 108 in the gate structure to be formed (see FIG. 1C), such that length L corresponds to the length of a gate channel for providing electrical conductivity between source and drain of the FET. Various other structures and layers for forming the FET or the GAA-FET are omitted for descriptive clarity. In particular, source channel pillar 104 and drain channel pillar 106 are shown to result in three (3) source channels and three (3) drain channels that connect to the gate channel and are formed from SiGe layers 112, such that intermediate Si layers 110 are to be removed or released. As noted, various numbers of channels can be formed in various implementations. Accordingly, FET structure 100 can be subject to selective etching of silicon adjacent to silicon-germanium, as disclosed in further detail herein. For example, SiGe layers 112 can be supported by spacers that enable release of Si layers 110 for the selective etching. In some implementations, a temporary spacer for the gate pillar can be installed before the gate material (e.g., a low k metal) is deposited at gate region 108, among other layers and structures for forming an operational FET.

FIG. 1B is a depiction of an FET structure 101 during fabrication, in some implementations. FET structure 101 is shown in a schematic depiction and is not necessarily drawn to scale or perspective. In FIG. 1B, FET structure 101 is substantially similar to FET structure 100 in FIG. 1A. However, in FET structure 101, selective etching of Si layers 110 has been performed to expose source channels and drain channels formed from SiGe layers 112. In various implementations, as disclosed herein, an etching process that does not use ionic species, such as a plasmaless etching process, or a remote plasma etching process is used to form FET structure 101.

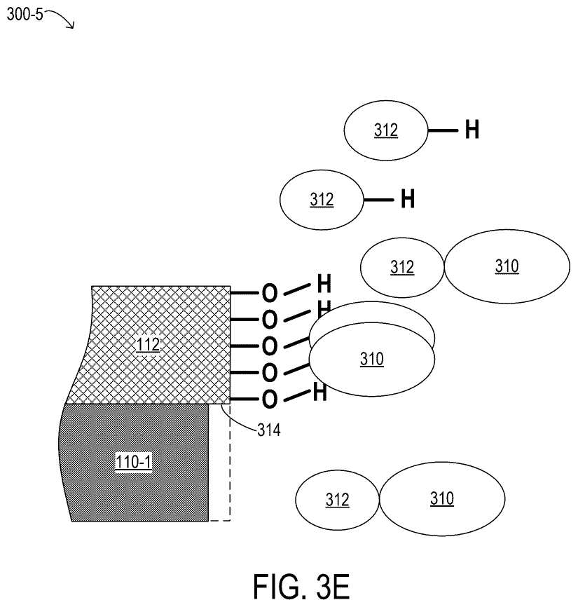

As shown, FET structure 101 comprises three (3) channels in the form of nanosheets comprised from SiGe layers 112, as described above with respect to FIG. 1A, in an exemplary implementation. As shown, FET structure 101 includes SiGe layers 112 that have been selectively etched to remove or release the adjacent Si layers 110, such as to the edges of gate region 108 where the gate structure will be formed in subsequent process steps. The selective etching back of Si layers 110 is depicted in further detail in FIGS. 3A-3D.

FIG. 1C is a depiction of an FET 102, in some implementations. FET 102 is shown as a GAA-FET in a schematic depiction and is not necessarily drawn to scale or perspective. In FIG. 1C, FET 102 is shown as a 3D depiction of having a gate structure 122 completed at the location of gate region 108 shown in FIGS. 1A and 1B. In FET 102, source channels 124 and drain channels 126 protrude horizontally from either side of gate structure 122 to enable connection to respective electrodes that can be formed in subsequent process steps. In FET 102, three (3) source/drain channels forming respective three (3) gate channels 116 passing internally through gate structure 122 are depicted in dashed lines.

As visible in FET 102 in FIG. 1C, a rectangular cross-sectional shape of the source/drain channels has a width W of SiGe layers 112 that corresponds to a width of each gate channel 116. As shown, gate channels 116 comprised of a gate dielectric are surrounded by gate structure 122 that is formed from a metal conductor to enable field-effect conduction at gate channel 116 to operate FET 102. The geometry of gate structure 122 and gate channels 116 surrounding the source/drain channels on all four sides gives rise to the gate-all-around (GAA) moniker. Accordingly, width W can correspond to a channel width and can be used to adjust the channel width of gate channel 116, in various implementations, to tailor FET 102 for a particular application, such as to drive higher current or for power savings. Specifically, the actual width of gate channel 116 for each SiGe layer 112 forming a source terminal and a drain terminal of the GAA-FET is given by (2×W)+(2×T) where T is a thickness of SiGe layer 112, while the length of gate structure 122 corresponds to L.

Furthermore, for forming the p-type GAA-FET, SiGe layer 112 can be p+ doped at or near the interface with gate structure 122 while a central portion of gate channel 116 (over the distance L) can comprise an n-type silicon-germanium core, surrounded by the gate dielectric. It is noted that FET 102 is a schematic illustration of a portion of the GAA-FET for descriptive purposes and that various other structures and layer can be included in the GAA-FET, such as source electrodes and drain electrodes for making respective circuit contacts to SiGe layer 112, also referred to as source terminals and drain terminals.

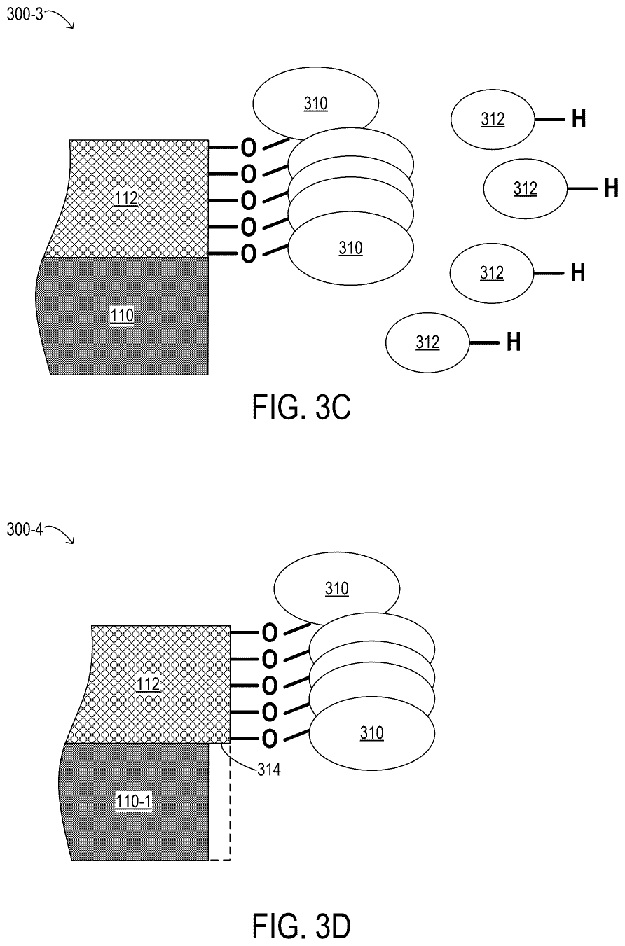

FIG. 2 is a flowchart depicting a method 200 for selective etching of silicon, in some implementations. Method 200 can be performed to fabricate the nanosheets of SiGe layers 112, as described above with respect to FIGS. 1A and 1B. Certain operations in method 200 can be omitted or rearranged in particular implementations.

Method 200 can begin at step 210 by forming a layered structure of alternating silicon and silicon-germanium nanosheets. The layered structure in step 210 can be channel pillar structure 118 in FIG. 1A. In some implementations, nanowires can be formed in step 210 instead of nanosheets. Step 210 can include epitaxial growth of crystalline silicon and silicon-germanium layers, such as on a suitable substrate. In particular implementations, the silicon-germanium nanosheets, or SiGe layers 112, can have about 70% or more silicon content, or about 30% or less germanium content.

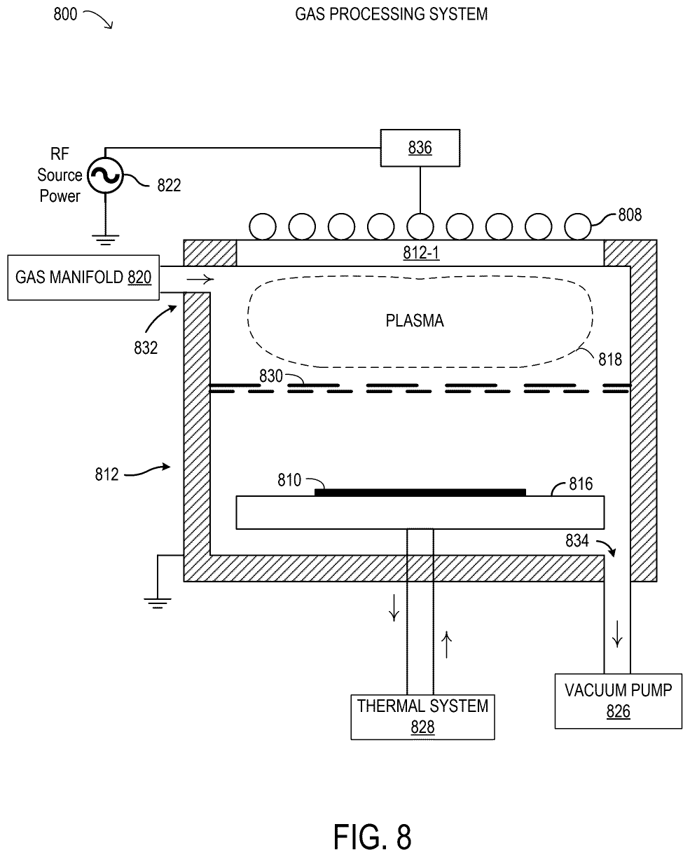

In method 200, at step 212, the silicon germanium nanosheets are selectively oxidized to deposit hydroxyl groups at the surface. In particular implementations, the oxidization in step 212 can be performed by exposure to oxygen. Table 1 below lists surface oxygen ratios in percentage for SiGe, SiGeB (boron-doped SiGe), and Si films under various stoichiometries and process conditions as approximate values, rather than corresponding to any specific implementation. In Table 1, the first two columns represent films formed using NO and O₂ as the oxygen source represent plasma processes, while the third column represents films formed using O₂ in a gas-phase process, such as with a molecular gas. In plasma based-processes for oxidation, a feeding gas can include O₂, NO, CO, CO₂ which are diluted in Ar, He, and/or N₂ as a carrier gas. The total flow rates of the gas can be adjusted as a parameter to tune a resident time of gas species. The reactive species in the remote plasma and the degree of surface reaction can also be controlled by power (100-90 W), chamber pressure (15-2000 mT), and temperature (−30-120 C), see also FIG. 8. For the gas phase oxidation, reactive feeding gas of O2, NO, and NO2 diluted in Ar and/or N2 as carrier gas. The wafer temperature can be kept at (100-300 C) and the resident time can be controlled to maximize the selectivity of oxidation between Si and SiGe.

TABLE 1
General surface oxygen ratios [%] of various Si containing films

| | NO (plasma | O₂ | O₂ |
|---|---|---|---|
| Film Composition | process) | (plasma process) | (gas-phase) |
| SiGe | 19 | 13 | 33 |
| SiGeB | 22 | 18 | 28 |
| Si | 3 | 5 | 10 |

As will be described in further detail below, the oxidation process can result in hydroxyl groups being selectively deposited on the silicon-germanium surface. The hydroxyl groups can form covalent oxygen bonds at the surface, that can be described as being adsorbed or attached to the silicon-germanium surface.

It is noted that a process time as well as a concentration of oxidant can be varied or optimized, such as to improve the selectivity of oxidation between Si and different materials, such as SiGe. One common feature of the methods and techniques described herein, is that SiGe oxidation is naturally faster or more pronounced compared to other materials. As a result, an oxidation rate for SiGe, which is an inherent material property, can be modulated or retarded relative to Si using the methods described herein. Another composition criteria that can be modified is the amount of Ge doping in SiGe, which can also affect the oxidation rate of SiGe.

The oxidizing chemistries and conditions described above are examples to demonstrate the chemical concepts of selective oxidation and etching of Si. In different embodiments, a range of chemistries and methods can be used.

At step 214 in method 200, the layered structure is exposed to a small molecule treatment. At step 214, the small molecule can have a first functional group and a second functional group. A “small molecule” as used herein can refer to a volatile molecule that is comprised of at least 2 functional groups. Upon reaction with the surface at a solid/gas interface, a first functional group can be chemisorbed on the surface, while a second functional group can be converted to a volatile by-product. The small molecule can potentially have additional functional groups that can impact a rate of surface reaction and/or the volatility of by-products, for example. The first functional group, such as a silicon-based functional group, can be adsorbed or attached to the surface, such as by forming a bond with the surface oxygen formed in step 212 selectively on the silicon-germanium nanosheets (e.g., SiGe layers 112). The reaction that forms the oxygen bond to the first functional group can release a hydrogen atom that bonds with the second functional group, which then forms a volatile molecule that can be removed as a gas, such as by applying a vacuum pump to a chamber where steps 212 and 214, among other steps in method 200, can be performed. Thus, as a result of step 214, the second functional group can remain bonded to SiGe layers 112 and can provide a passivation layer to prevent etching of the SiGe layers 112 in step 216, resulting in selective etching of Si layers 110.

At step 216 in method 200, the layered structure is exposed to an etchant gas to selectively etch at least a portion of the silicon nanosheets and expose a portion of the silicon germanium nanosheets. At step 216, a gas-phase etching process can be performed absent an ionic plasma, such as using a remote plasma generated from an ionic plasma by removing ions and electrons to leave free radical species in the remote plasma. The etchant gas used in step 216 absent ionic species or absent free electrons can be referred to as a molecular etchant gas and can result in chemical reactions at the surface for the etching process. The gas-phase etching process in step 216 can accordingly be an isotropic etch process, such as at a given pressure and temperature. At step 216, some or all of the silicon nanosheets can be removed by etching, and since the layered structure includes alternating silicon and silicon-germanium nanosheets, at least some of the silicon-germanium nanosheets can be exposed. It is noted that the exposed silicon-germanium can be etched away to a degree due to the isotropic etch process, also referred to as ‘undercutting’ of SiGe layers 112. Therefore, to avoid excessive undercutting of the silicon-germanium nanosheets, method 200 may involve shorter etch durations or periods that remove a small amount of silicon at one time and that are repeated (see step 218) along with steps 212 and 214 to passivate any newly exposed silicon-germanium surfaces with the small molecule treatment, as described above.

At step 218, a decision can be made whether the silicon layer etch is complete. The decision in step 218 can result from a measurement or an estimation of an actual etch condition in some implementations. In particular implementations, the decision in step 218 is made prior to begin of method 200, such as with consideration of etch conditions, etch rates for silicon, a total thickness of silicon to be removed, and an acceptable degree of undercutting of silicon-germanium. As a result, each time step 216 is performed, a maximum duration that is predetermined can define a duration of step 216. When a total duration for the desired silicon etch in method 200 is greater than the maximum duration for step 216, the decision in step 218 can be made based on a number of predetermined iterations of step 216 to complete the total duration. In other words, method 200 may be used for incremental etching in a cyclic manner. When the result of step 218 is YES, method 200 can end at step 220. When the result of step 218 is NO, method 200 can loop back to step 212 in particular implementations.

FIGS. 3A through 3E are depictions of a process 300 for selective etching of silicon, in some implementations. Process 300 can be performed to fabricate the nanosheets of SiGe layers 112, as described above with respect to FIGS. 1A and 1B. Certain operations in process 300 can be omitted or rearranged in particular implementations. In FIGS. 3A, 3B, 3C, 3D, and 3E, surface reactions are depicted on a portion of exposed surfaces of channel pillar structure 118 as shown in FIG. 1A, such as at an edge portion comprising one SiGe layer 112 and one Si layer for descriptive clarity, in an exemplary manner. It is noted that the surface reactions shown and described herein can generally be observed on all exposed surfaces of SiGe layer 112, including surfaces of SiGe layer 112 that are shown without reactions in FIGS. 3A, 3B, 3C, and 3D, for purposes of descriptive clarity.

In FIG. 3A, process step 300-1 may include oxidation of silicon-germanium adjacent to silicon, such as in channel pillar structure 118 in FIG. 1A. For example, a gas-phase oxidation process with O2 gas as described in Table 1 can be used to selectively oxidize SiGe layers 112. In process step 300-1, hydroxyl groups are shown selectively adsorbed or attached to SiGe layer 112. Process step 300-1 may depict a result of step 212 in method 200.

In FIG. 3B, process step 300-2 depicts exposure to a small molecule having a first functional group 310 and a second functional group 312. In FIG. 3C, process step 300-3 shows a result of the small molecule treatment. In process step 300-3, first functional group 310 has bonded with surface oxygen atoms, while second functional group 312 has been reduced with hydrogen and can be pumped away as a volatile gas. First functional group 310 accordingly has formed a passivation layer on SiGe layer 112 selectively, while Si layer 110 remains exposed for removal by etching. Process steps 300-2 and 300-3 may depict step 214 in method 200 and may be performed at a process pressure and temperature. In particular, thermal activation of the small molecule treatment depicted in process steps 300-2 and 300-3 can be used, such as by using a process temperature that is between 100° C. and 150° C., or about 120° C. to 130° C. in particular implementations, that can depend on the chemical composition of the first functional group or the second functional group.

In FIG. 3D, process step 300-4 shows a result of selective etching of Si layer 110-1 showing some removal of silicon. The selective etching can be performed using an etchant gas that is nonionic, such as a molecular gas or a remote plasma. The removal of silicon can result in exposure of SiGe layer 112 at a surface portion 314, that can be subject to undercutting during etching. Therefore, when surface portion 314 exceeds a minimum size or area that can be predetermined, process 300 can be restarted such that surface portion 314 is subsequently oxidized and passivated for further selective etching of silicon. In this manner, surface portion 314 remains a desirably small area, such that a relatively clean surface of SiGe layer 112 with preservation of a desired material volume (and cross-sectional area) of silicon-germanium can be achieved. For example, a surface roughness below desired tolerances for source channels 124 and drain channels 126 can be realized in this manner (see FIG. 1C).

As shown in process 300, the small molecule treatment involves exposure to a small molecule having first functional group 310 and second functional group 312. The small molecule can be selected based on certain properties of first functional group 310 and second functional group 312. For example, first functional group 310 and second functional group 312 can be chosen such that the reactions depicted in process step 300-3 are thermodynamically favored and can kinetically be initiated and proceed. Furthermore, first functional group 310 can be selected to provide etchant selectivity to Si layer 110. Accordingly, first functional group 310 can be selected to preferentially bond to the surface oxide layer at SiGe layer 112. For example, first functional group 310 can include a silane, and in particular, a methylsilane functional group, such as a dimethylsilane or trimethylsilane (TMS), in particular implementations. When first functional group 310 includes a silane, the etchant gas chemistry can comprise a combination of ammonia (NH3) and fluorine (F2) in some implementations. In some implementations, one or more methyl groups in first functional group 310 can be replaced with another ligand, such as another hydrocarbon group, a disulfide, or a phosphasilene. Second functional group 312 can be selected for having a suitable reduction potential to form a volatile gas species upon hydrogenation. For example, second functional group 312 can include an amine, a chloride, a bromide, or a fluoride. In particular implementations, second functional group 312 can be methylamine, trimethylamine, or dimethlyamine (DMA).

In FIG. 3E, process step 300-5 shows another embodiment of process 300, in which all steps in the cyclic chemical process described are performed simultaneously, such as in a single operation or step. In process step 300-5, each of process steps 3A, 3B, 3C, and 3D, such as corresponding to method steps 212, 214, and 216, are performed simultaneously, such as in process chamber 812 using gas processing system 800 (see FIG. 8). Accordingly, each species and reaction product may be present during process step 300-5, as shown in FIG. 3E.

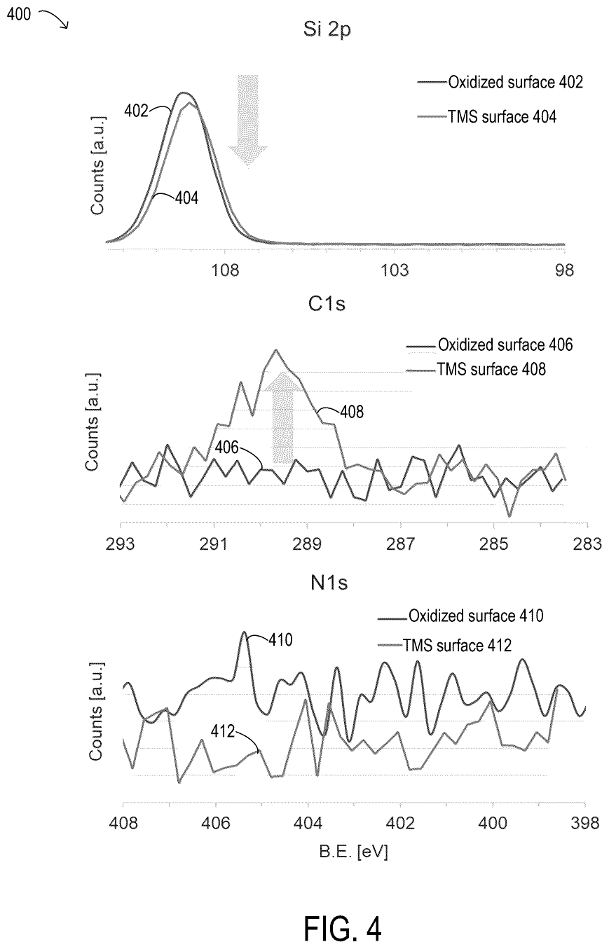

FIG. 4 is a multiplot 400 depicting selected x-ray photoelectron spectra (XPS), in some implementations. In FIG. 4, multiplot 400 includes XPS data for SiGe layer 112 when the small molecule is DMA-TMS, with each plot including two spectra for an oxidized surface as shown in FIG. 3A and for a TMS adsorbed surface as shown in FIG. 3C when first functional group 310 is TMS. A top plot in multiplot 400 shows XPS data for a photoelectron energy range corresponding to a silicon 2p orbital (Si 2p). The top plot in multiplot 400 indicates a reduction in peak intensity and a slight shift to lower energy from an oxidized surface plot 402 to a TMS surface plot 404 that can indicate the presence of Si—O bonds for TMS. A middle plot in multiplot 400 shows XPS data for a photoelectron energy range corresponding to a carbon 1s orbital (C 1s) peak resulting from the methyl groups of TMS, visible for a TMS surface plot 408, while no such peak is present for an oxidized surface plot 406. A lower plot in multiplot 400 shows XPS data for a photoelectron energy range corresponding to a nitrogen 1s orbital (N 1s) that shows no appreciable rise from a baseline value (e.g., no N 1s peak) for an oxidized surface plot 410 and for a TMS surface pot 412 indicating an absence of nitrogen and thus, an absence of any Si-DMA (or epi-Si(DMA)) bonds at the surface, which is consistent with removal of DMA as a gas molecule.

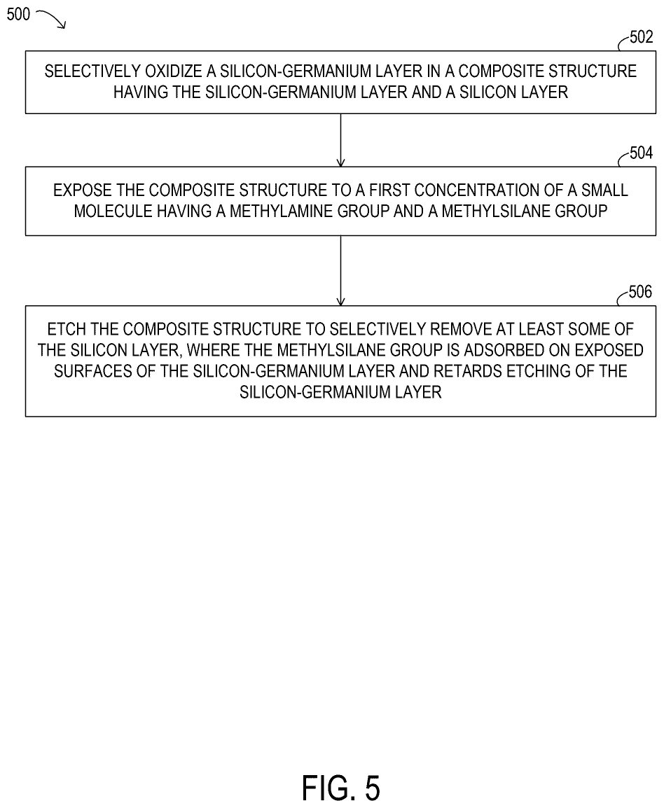

Turning now to FIG. 5, a flowchart depicts a method 500 of selective etching of silicon, in some implementations. It is noted that some portions of method 500 may be omitted or rearranged in certain implementations.

Method 500 may begin at step 502 by selectively oxidizing a silicon-germanium layer in a composite structure having the silicon-germanium layer and a silicon layer. Step 502 can include causing a hydroxyl group to selectively attach to the silicon-germanium layer. At step 504, the composite structure is exposed to a first concentration of a small molecule having a methylamine group and a methylsilane group. The methylsilane group can be a trimethylsilane group. As a result of step 504, the methylsilane group can be selectively adsorbed on the silicon-germanium layer and the methylamine group can form a volatile species. The methylamine group can be a dimethylamine and the gas species can be dimethylamine gas. Thus, the small molecule can be dimethylamine trimethylsilane. At step 506, the composite structure is etched to selectively remove at least some of the silicon layer, where the methylsilane group is adsorbed on exposed surfaces of the silicon-germanium layer and retards etching of the silicon-germanium layer. Step 506 can include isotropically etching the composite structure using a nonionic etchant gas including a molecular gas or a remote plasma. The silicon-germanium layer can form a source channel or a drain channel of a gate-all-around field effect transistor (GAA-FET).

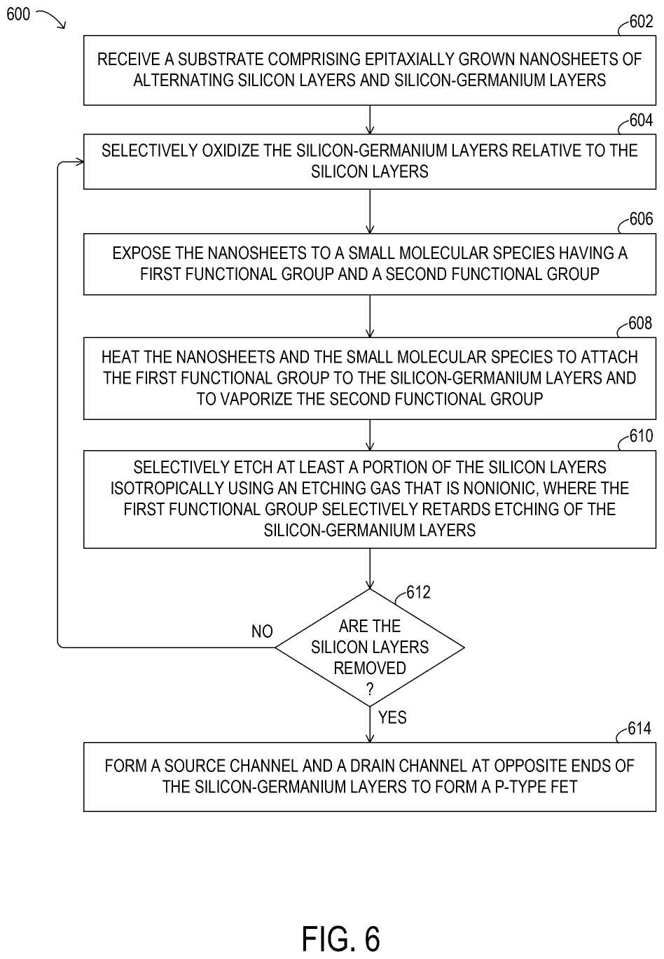

FIG. 6 is a flowchart of a process 600 of selective etching of silicon, in some implementations. It is noted that some portions of process 600 may be omitted or rearranged in certain implementations. Process 600 can represent a fabrication process to form at least certain portions of an FET.

Process 600 may begin at step 602 by receiving a substrate comprising epitaxially grown nanosheets of alternating silicon layers and silicon-germanium layers. At step 604, the silicon-germanium layers are selectively oxidized relative to the silicon layers. Selectively oxidizing the silicon-germanium layers in step 602 can include causing hydroxyl groups to selectively attach to the silicon-germanium layers rather than the silicon layers. At step 606, the nanosheets are exposed to a small molecular species having a first functional group and a second functional group. The first functional group can include a methylsilane group. At step 608, the nanosheets and the small molecular species are heated to attach the first functional group to the silicon-germanium layers and to vaporize the second functional group. Heating the nanosheets and the small molecular species in step 608 can include reducing the second functional group that includes one of: a methylamine group, chlorine (Cl), bromine (Br), or fluorine (F). At step 610, at least a portion of the silicon layers are selectively etched isotropically using an etching gas that is nonionic, where the first functional group selectively retards etching of the silicon-germanium layers. The etching gas can include a molecular gas and/or a remote plasma. At step 612, a decision is made whether the silicon layers are removed. The decision in step 612 may be based on a metrology result or may be based on a predetermined etch amount or total etch duration (see also step 218 in FIG. 2). When the result of step 612 is NO, process 600 may loop back to step 604. When the result of step 612 is YES, at step 614, a source channel and a drain channel are formed at opposite ends of the silicon-germanium layers to form a p-type FET. The p-type FET can be a GAA-FET.

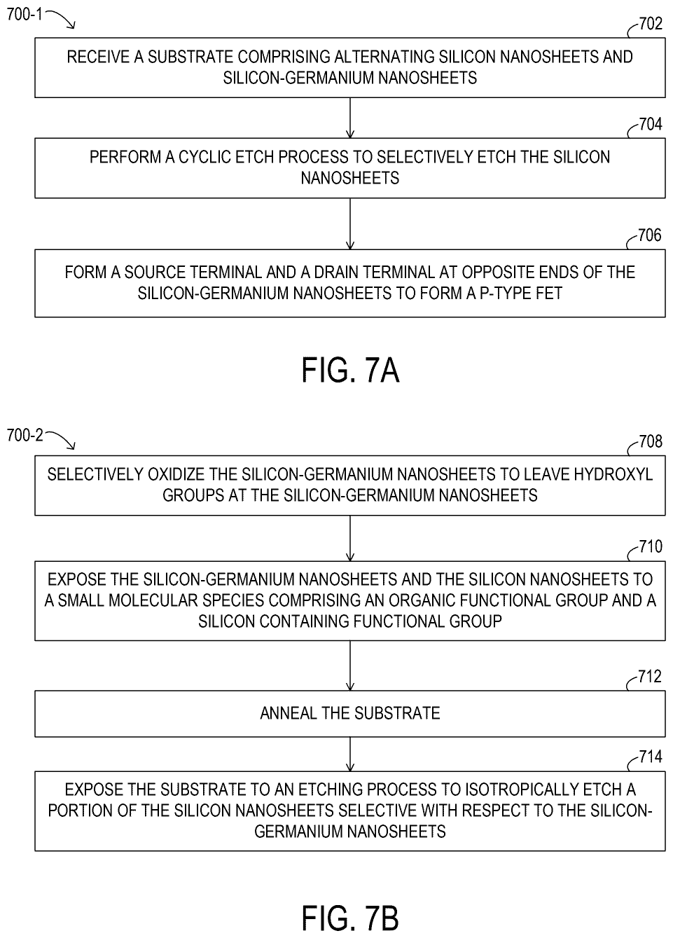

FIGS. 7A and 7B are flowcharts of a process 700 of selective etching of silicon, in some implementations. It is noted that some portions of process 700 may be omitted or rearranged in certain implementations. Process 700 can represent a fabrication process to form at least certain portions of a FET. FIG. 7A describes a process 700-1 for performing a cyclic etch process, while FIG. 7B describes a process 700-2 that comprises the steps of the cyclic etch process that can be repeated.

Process 700-1 in FIG. 7A may begin at step 702 by receiving a substrate comprising alternating silicon nanosheets and silicon-germanium nanosheets. The nanosheets received in step 702 can include epitaxially grown silicon nanosheets and silicon-germanium nanosheets. At step 704, a cyclic etch process is performed to selectively etch the silicon nanosheets. At step 706, a source terminal and a drain terminal are formed at opposite ends of the silicon-germanium nanosheets to form a p-type FET. The FET can be a GAA-FET including silicon-germanium nanosheets corresponding to respective source channels and three drain channels.

Process 700-2 in FIG. 7B may begin at step 708, by selectively oxidizing the silicon-germanium nanosheets to leave hydroxyl groups at the silicon-germanium nanosheets. At step 710, the silicon-germanium nanosheets and the silicon nanosheets are exposed to a small molecular species comprising an organic functional group and a silicon containing functional group. The small molecular species can be dimethylamine trimethylsilane (DMA-TMS) in particular implementations. At step 712, the substrate is annealed. At step 712, the silicon-germanium nanosheets and the silicon nanosheets can be heated with the small molecular species to adsorb the methylsilane group on the silicon-germanium nanosheets and to vaporize the methylamine group. At step 714, the substrate is exposed to an etching process to isotropically etch a portion of the silicon nanosheets selective with respect to the silicon-germanium nanosheets.

FIG. 8 is a depiction of a gas processing system 800 in one implementation. FIG. 8 is a schematic depiction and is not necessarily drawn to scale or perspective. Gas processing system 800, as shown, is indicative of various specific implementations and is not limited to any particular design or specific process equipment. Accordingly, in various implementations, gas processing system 800 may include more or fewer elements than depicted in FIG. 8.

As shown in FIG. 8, gas processing system 800 includes a process chamber 812 that can be pumped down to a desired vacuum pressure, such as by using a vacuum pump 826 in fluid communication with process chamber 812 via a gas outlet 834. Vacuum pump 826 can be a turbo molecular pump in some implementations, among other types of pumps. Process chamber 812 is configured to load a semiconductor substrate 810 (or simply substrate 810), such as a silicon wafer on which multiple circuit designs in the form of multiple IC die can be fabricated, among other types and materials of substrates. In particular implementations, semiconductor substrate 810 may be 300 mm in diameter, among other sizes. Semiconductor substrate 810 may accordingly be used in process chamber 812 at various stages of fabrication. As described herein, semiconductor substrate 810 may be used form various types of ICs and components, including GAA-FETs (see FIG. 1C).

As shown in FIG. 8, semiconductor substrate 810 is supported by a chuck 816 that can retain and secure semiconductor substrate 810 in a desired aligned position with respect to chuck 816. In various implementations, chuck 816 may comprise an electrostatic chuck configured to hold a backside of substrate 810, while a frontside of substrate 810 opposite the backside can be exposed to gas conditions inside process chamber 812. Chuck 816 can also be capable of loading and unloading semiconductor substrate 810 from process chamber 812, such as with the cooperation of other equipment, such as handling robots or equipment. Chuck 816 can be mounted within process chamber 812 in a manner that enables raising or lowering of semiconductor substrate 810 within process chamber 812. For example, after an interior volume of process chamber 812 is pumped down to a sufficient vacuum pressure, such as a sufficiently low vacuum pressure, a gas manifold 820 can meter and deliver a gas mixture in fluid communication with process chamber 812. Gas manifold 820 may include gas canisters, throttle valves, flow meters, pressure sensors, among other components, to maintain a controlled gas flow in process chamber 812.

In FIG. 8, gas manifold 820 can be configured to mix or provide any number of source gases to process chamber 812 and can further change a composition or a flow rate associated with the gas mixture so provided. For example, gas manifold 820 can independently control a supply of a constituent gas in the gas mixture, at a desired time, such as in response to an instruction from process control equipment that controls gas processing system 800. An inlet 832 for the gas mixture so provided by gas manifold 820 is shown in fluid communication with process chamber 812.

The gas mixture introduced into process chamber 812 can be used for isotropic etching of substrate 810 without employing a plasma having ionic species. For example, in various implementations, isotropic etching using the gas mixture can be controlled by a composition of the gas mixture, by concentrations of constituent gases in the gas mixture, by a pressure within process chamber 812, and/or by temperature conditions at substrate 810, or more generally within process chamber 812. The isotropic etching using process chamber 812 using the gas mixture can accordingly involve molecules in the gas mixture that undergo reactions, such as the small molecule treatment and selective etching of silicon described previously.

In some implementations, isotropic etching of substrate 810 in process chamber 812 can be performed by using a remote plasma that contains free radical species, but is nonionic and does not include ions or electrons. Accordingly, process chamber 812 can be used to apply the remote plasma for the small molecule treatment and selective isotropic etching of silicon, as disclosed herein.

To generate the remote plasma, a plasma 818 can be generated at a top portion of process chamber 812, as described below, and can pass through a grid electrode 830 that is permeable and conductive, such as being formed as a metallic sieve that is grounded to process chamber 812. When plasma 818 passes through grid electrode 830, ionic species and electrons can be removed from the plasma to leave free radical and molecules that are nonionic species that comprise the remote plasma. Plasma 818 can pass through grid electrode 830 to remove the ionic species leaving the remote plasma to isotropically etch substrate 810.

To generate plasma 818 (in order to generate the remote plasma for isotropic etching), the gas mixture introduced into process chamber 812 can be ionized by an RF source power 822. As shown, plasma 818 is a glow discharge, ignited and sustained using electromagnetic (EM) power from radio frequency (RF) source power 822 coupled to a first electrode 808 that is configured to generate EM fields inside process chamber 812. In some implementations, gas processing system 800 can be configured in an inductively coupled plasma (ICP) mode, where RF source power 822 is coupled inductively to the gas mixture to generate plasma 818. In some implementations, RF source power 822 can be used in a capacitively coupled plasma (CCP) mode. Accordingly, first electrode 808 is shaped as a planar coil disposed over a top portion of process chamber 812, indicated as a dielectric window 812-1. A first impedance matching circuit 836 in the signal path between RF source power 822 and first electrode 808 can suppress reflections to improve RF power transfer efficiency to plasma 818.

In gas processing system 800, an extent to which the gas mixture from gas manifold 820 is excited to plasma 818 can depend on electrical power supplied by RF source power 822 that accordingly can control a gas chemistry of plasma 818 in this manner. As plasma 818 forms, a dark region or sheath surrounds plasma 818 and results in an electric field between plasma 818 and process chamber 812 that serves to contain plasma 818. Plasma 818 may accordingly include molecules, free radicals, excited radicals, ions, and electrons, of which the nonionic species (molecules and free radicals) remain in the remote plasma after passing through grid electrode 830.

As a result of the controls and arrangement of elements in gas processing system 800 shown in FIG. 8, selective isotropic etching of silicon using the gas mixture from gas manifold 820 or a remote plasma generated from the gas mixture, can be performed in process chamber 812 on semiconductor substrate 810. For example, gas manifold 820 can supply gases for applying the various steps for selective etching of silicon shown in FIGS. 3A-3D. Gas manifold 820 can provide oxygen along with other gases for oxidation of SiGe layers 112 in FIG. 3A. Gas manifold 820 can provide the small molecule having first functional group 310 and second functional group 312 in FIG. 3B, for the small molecule treatment to selectively passivate SiGe layers 112. Gas manifold 820 can then provide the gas mixture for etching Si layers 110, whether as a molecular gas or as a remote plasma, for isotropic etching. Process chamber 812 can also regulate a pressure and a temperature for the isotropic etching of substrate 810.

Chemical reactions being sensitive to temperature that can vary in substrate 810 during etching, such during selective etching of silicon adjacent to silicon-germanium, as disclosed herein, gas processing system 800 is equipped with a thermal system 828 configured to maintain substrate 810 at a desired temperature, such as by regulating cooling and/or heating of substrate 810. Accordingly, thermal system 828 may comprise liquid coolant, cooling gas, pumps, heater elements, power supplies, and temperature sensors, among other equipment for regulating cooling and/or heating. In particular implementations, chuck 816 can be mounted on a pedestal having a platen supported by a stem, while thermal system 828 may be configured with conduits or gas flow lines for accessing the platen through the stem of the pedestal on which chuck 816 is mounted, such as in order to circulate a coolant (e.g., He or L N₂) within the pedestal and flow the coolant through grooves in the platen in proximity to the backside of substrate 810. In particular implementations, electrical heating elements may be located within the pedestal proximate the backside of substrate 810 and controlled by electrical power supplied by thermal system 828, in order to maintain a desired temperature at substrate 810.

As shown included with gas processing system 800 in FIG. 8, thermal system 828 can supply a backside of substrate 810 with circulating coolant. A helium (He) coolant can be used to regulate a temperature of semiconductor substrate 810 during etching, which imparts thermal energy to semiconductor substrate 810. A liquid nitrogen (L N₂) coolant can also be circulated, in addition to or instead of He coolant in different implementations, to provide regulated cryogenic cooling, as desired. It is noted that thermal system 828 can include various temperature sensors and instrumentation for measuring temperatures associated with a heating/cooling circulation loop for chuck 816 and semiconductor substrate 810, and can also receive temperature signals and values, such as provided for process chamber 812, in different implementations. Furthermore, during etching, vacuum pump 826 can evacuate volatile byproducts of the etch process, such as second functional group 312 described above with respect to FIGS. 3A-3D. In this manner, vacuum pump 826 can regulate a desired pressure within process chamber 812, among other equipment for pressure regulation. It is noted that other process controls and equipment can be used in different implementations of gas processing system 800, such as vacuum pumps, temperature controls, heaters, coolers, gas filters, handling equipment, associated process chambers, among other equipment.

Accordingly, in particular implementations of selective etching of silicon performed using gas processing system 800, such as to fabricate a GAA-FET, the following process parameters given in Table 2 can apply, such as for an isotropic gas etch process for semiconductor substrate 810, in which the units used are Watts [W], Hertz [Hz], percent [%], millitorr [mTorr], standard cubic centimeter per minute [SCCM], degrees Celsius [C], and minutes [min].

TABLE 2
Process parameters for gas processing system 800.

| Parameter Description | Process Parameter [Units] |
|---|---|
| RF source power 822 — Electrical | Power [W] |
| Power | |
| Vacuum pump 826 | Chamber Pressure [mTorr] |
| Pressure | |
| Gas manifold 820 | Flow Rate [SCCM] |
| Gas Flow | |
| Chuck 816, thermal system 828 | Temperature [C.] |
| Temperature | |
| Etch Duration | Time [min] |

As disclosed herein, a process for forming at least portions of an FET includes receiving a substrate comprising epitaxially grown nanosheets of alternating silicon layers and silicon-germanium layers, selectively oxidizing the silicon-germanium layers relative to the silicon layers, exposing the nanosheets to a small molecular species comprising a first functional group and a second functional group. The process also includes heating the nanosheets and the small molecular species to attach the first functional group to the silicon-germanium layers and to vaporize the second functional group, and selectively etching at least a portion of the silicon layers isotropically using an etching gas, where the first functional group selectively retards etching of the silicon-germanium layers.

Example implementations of the invention are described below. Other implementations can also be understood from the entirety of the specification as well as the claims filed herein.

Example 1. A method including: selectively oxidizing a silicon-germanium layer in a composite structure having the silicon-germanium layer and a silicon layer adjacent to the silicon-germanium layer; and exposing the composite structure to a first concentration of a small molecule including a methylamine group and a methylsilane group.

Example 2. The method of example 1, further including: etching the composite structure to selectively remove at least some of the silicon layer, where the methylsilane group is adsorbed on exposed surfaces of the silicon-germanium layer and retards etching of the silicon-germanium layer.

Example 3. The method of one of examples 1 or 2, where the methylamine group is a dimethylamine.

Example 4. The method of one of examples 1 to 3, where the methylsilane group is a trimethylsilane group.

Example 5. The method of one of examples 1 to 4, where the small molecule is dimethylamine trimethylsilane.

Example 6. The method of one of examples 1 to 5, where etching the composite structure further includes: isotropically etching the composite structure using a nonionic etchant gas including a molecular gas or a remote plasma.

Example 7. The method of one of examples 1 to 6, where the silicon-germanium layer forms a source channel or a drain channel of a gate-all-around field effect transistor (GAA-FET).

Example 8. The method of one of examples 1 to 7, where the GAA-FET is a p-type FET.

Example 9. A process for forming a field effect transistor (FET), including: receiving a substrate including epitaxially grown nanosheets of alternating silicon layers and silicon-germanium layers; selectively oxidizing the silicon-germanium layers relative to the silicon layers; exposing the nanosheets to a small molecular species including a first functional group and a second functional group; and heating the nanosheets and the small molecular species to attach the first functional group to the silicon-germanium layers and to vaporize the second functional group; and selectively etching at least a portion of the silicon layers isotropically using an etching gas, where the first functional group selectively retards etching of the silicon-germanium layers.

Example 10. The process of example 9, where the first functional group includes a methylsilane group.

Example 11. The process of one of examples 9 or 10, where heating the nanosheets and the small molecular species further includes reducing the second functional group that includes one of: a methylamine group, chlorine (Cl), bromine (Br), or fluorine (F).

Example 12. The process of one of examples 9 to 11, further including: forming a source channel and a drain channel at opposite ends of the silicon-germanium layers, where the FET is a p-type FET.

Example 13. The process of one of examples 9 to 12, where selectively oxidizing the silicon-germanium layers further includes: causing a hydroxyl group to selectively attach to the silicon-germanium layers, and where the etching gas includes a molecular gas or a remote plasma.

Example 14. The process of one of examples 9 to 13, further including: repeating, until the silicon layers are removed, the selectively oxidizing the silicon-germanium layers, the exposing the nanosheets to the small molecular species, the heating the nanosheets and the small molecular species, and the selectively etching at least a portion of the silicon layers; and where the FET is a gate-all-around FET (GAA-FET).

Example 15. A fabrication process for a field effect transistor (FET), the fabrication process including: receiving a substrate including alternating silicon nanosheets and silicon-germanium nanosheets; and performing a cyclic etch process to selectively etch the silicon nanosheets, each cycle of the cyclic etch process including: selectively oxidizing the silicon-germanium nanosheets to leave hydroxyl groups at the silicon-germanium nanosheets, exposing the silicon-germanium nanosheets and the silicon nanosheets to a small molecular species including an organic functional group and a silicon containing functional group, annealing the substrate, and exposing the substrate to an etching process to isotropically etch a portion of the silicon nanosheets selective with respect to the silicon-germanium nanosheets.

Example 16. The fabrication process of example 15, where, during the annealing, the silicon containing functional group adsorbs on the silicon-germanium nanosheets and the organic functional group is vaporized.

Example 17. The fabrication process of one of examples 15 or 16, where exposing the substrate to the etching process further includes: selectively etching the silicon nanosheets using a nonionic species including a molecular etchant gas or a remote plasma.

Example 18. The fabrication process of one of examples 15 to 17, where the small molecular species is dimethylamine trimethylsilane.

Example 19. The fabrication process of one of examples 15 to 18, where the organic functional group includes methylamine and the silicon containing functional group includes methylsilane.

Example 20. The fabrication process of one of examples 15 to 19, further including: forming a source terminal and a drain terminal at opposite ends of the silicon-germanium nanosheets, where the FET is a p-type gate-all-around FET (GAA-FET).

While this disclosure has been described with reference to illustrative implementations, this description is not intended to be construed in a limiting sense. Various modifications and combinations of the illustrative implementations, as well as other implementations, will be apparent to persons skilled in the art upon reference to the description. It is therefore intended that the appended claims encompass any such modifications or implementations.

What is claimed is:

1. A method comprising:
selectively oxidizing a silicon-germanium layer in a composite structure having the silicon-germanium layer and a silicon layer adjacent to the silicon-germanium layer; and
exposing the composite structure to a first concentration of a small molecule comprising a methylamine group and a methylsilane group.

2. The method of claim 1, further comprising:
etching the composite structure to selectively remove at least some of the silicon layer, wherein the methylsilane group is adsorbed on exposed surfaces of the silicon-germanium layer and retards etching of the silicon-germanium layer.

3. The method of claim 1, wherein the methylamine group is a dimethylamine.

4. The method of claim 3, wherein the methylsilane group is a trimethylsilane group.

5. The method of claim 4, wherein the small molecule is dimethylamine trimethylsilane.

6. The method of claim 2, wherein etching the composite structure further comprises:
isotropically etching the composite structure using a nonionic etchant gas including a molecular gas or a remote plasma.

7. The method of claim 6, wherein the silicon-germanium layer forms a source channel or a drain channel of a gate-all-around field effect transistor (GAA-FET).

8. The method of claim 7, wherein the GAA-FET is a p-type FET.

9. A process for forming a field effect transistor (FET), comprising:
receiving a substrate comprising epitaxially grown nanosheets of alternating silicon layers and silicon-germanium layers;
selectively oxidizing the silicon-germanium layers relative to the silicon layers;
exposing the nanosheets to a small molecular species comprising a first functional group and a second functional group; and
heating the nanosheets and the small molecular species to attach the first functional group to the silicon-germanium layers and to vaporize the second functional group; and
selectively etching at least a portion of the silicon layers isotropically using an etching gas, wherein the first functional group selectively retards etching of the silicon-germanium layers.

10. The process of claim 9, wherein the first functional group comprises a methylsilane group.

11. The process of claim 9, wherein heating the nanosheets and the small molecular species further comprises reducing the second functional group that includes one of: a methylamine group, chlorine (Cl), bromine (Br), or fluorine (F).

12. The process of claim 9, further comprising:
forming a source channel and a drain channel at opposite ends of the silicon-germanium layers, wherein the FET is a p-type FET.

13. The process of claim 9, wherein selectively oxidizing the silicon-germanium layers further comprises:
causing a hydroxyl group to selectively attach to the silicon-germanium layers,
and wherein the etching gas comprises a molecular gas or a remote plasma.

14. The process of claim 9, further comprising:
repeating, until the silicon layers are removed, the selectively oxidizing the silicon-germanium layers, the exposing the nanosheets to the small molecular species, the heating the nanosheets and the small molecular species, and the selectively etching at least a portion of the silicon layers; and
wherein the FET is a gate-all-around FET (GAA-FET).

15. A fabrication process for a field effect transistor (FET), the fabrication process comprising:
receiving a substrate comprising alternating silicon nanosheets and silicon-germanium nanosheets; and
performing a cyclic etch process to selectively etch the silicon nanosheets, each cycle of the cyclic etch process comprising:
selectively oxidizing the silicon-germanium nanosheets to leave hydroxyl groups at the silicon-germanium nanosheets,
exposing the silicon-germanium nanosheets and the silicon nanosheets to a small molecular species comprising an organic functional group and a silicon containing functional group,
annealing the substrate, and
exposing the substrate to an etching process to isotropically etch a portion of the silicon nanosheets selective with respect to the silicon-germanium nanosheets.

16. The fabrication process of claim 15, wherein, during the annealing, the silicon containing functional group adsorbs on the silicon-germanium nanosheets and the organic functional group is vaporized.

17. The fabrication process of claim 15, wherein exposing the substrate to the etching process further comprises:
selectively etching the silicon nanosheets using a nonionic species comprising a molecular etchant gas or a remote plasma.

18. The fabrication process of claim 15, wherein the small molecular species is dimethylamine trimethylsilane.

19. The fabrication process of claim 15, wherein the organic functional group comprises methylamine and the silicon containing functional group comprises methylsilane.

20. The fabrication process of claim 15, further comprising:
forming a source terminal and a drain terminal at opposite ends of the silicon-germanium nanosheets, wherein the FET is a p-type gate-all-around FET (GAA-FET).
